(19) United States
(12) Patent Application Publication
(10) Pub. No.: US 2020/0014108 A1
(43) Pub. Date: Jan. 9, 2020

(54) ANTENNA DEVICE

(71) Applicant: Advanced Wireless & Antenna INC., New Taipei City (TW)

(72) Inventor: I-Wei Tseng, New Taipei City (TW)

(73) Assignee: Advanced Wireless & Antenna INC., New Taipei City (TW)

(21) Appl. No.: 16/449,348

(22) Filed: Jun. 22, 2019

(30) Foreign Application Priority Data
Jul. 4, 2018 (TW) 107209064

(51) Int. Cl. H01Q 5/328; H01Q 5/20; G01R 29/10; H01Q 1/24; H01Q 1/44; H01Q 9/04; H01Q 1/36

(52) U.S. Cl. CPC H01Q 5/328; H01Q 5/20; G01R 29/10; H01Q 1/36; H01Q 1/44; H01Q 9/045; H01Q 1/24

(57) ABSTRACT

The disclosure provides an antenna device including an antenna element, a feeding portion, a filtering circuit, and a sensing circuit. The antenna element transmits or receives a radiation signal, wherein the radiation signal includes at least one of a first component and a second component, and a frequency band of the first component is lower than a frequency band of the second component. The feeding portion is coupled to the antenna element. The filtering circuit is coupled to the feeding portion, receives the radiation signal via the feeding portion and filters the second component of the radiation signal to generate a sensing signal. The sensing circuit is coupled to the filtering circuit, receives the sensing signal and determines whether a human body approaches the antenna device based on the sensing signal.

### CROSS-REFERENCE TO RELATED APPLICATION

This application claims the priority benefit of Taiwan patent application serial no. 107209064, filed on Jul. 4, 2018. The entirety of the above-mentioned patent application is hereby incorporated by reference herein and made a part of the specification.

### BACKGROUND

### Technical Field

The disclosure relates to an antenna device and more particularly, to an antenna device which provides a single antenna element with both a radiation signal function and a sensing function.

### Description of Related Art

Along with rapid development in the wireless communication technique, wireless terminals, such as smart cell phones, have been widely applied, and sizes thereof are also gradually developed toward miniaturization. However, while the sizes of the wireless terminals are miniaturized, not only the difficulty in designing related structures is increased, but also electromagnetic radiation to human bodies from the wireless terminals is also correspondingly intensified.

At present, an indicator for measuring the electromagnetic radiation to a human body from an antenna is a specific absorption rate (SAR), especially referring to an electromagnetic wave energy absorption rate. According to the specific definition of the SAR, under the influence of an external electromagnetic field, an induced electromagnetic field is generated in a human body, and because all kinds of organs in the human body are lossy media, the electromagnetic field in the body will generate an induced current, which causes the human body to be able to absorb and dissipate the electromagnetic energy. Such process may be represented by the SAR, and a meaning of the SAR lies in the electromagnetic power absorbed or consumed by a human tissue per unit mass, of which the unit is W/kg or mW/g. The Federal Communications Commission (FCC) definitely stipulates maximal SARs which are permitted during interactions between various wireless terminals and human bodies. In addition, the FCC also stipulates that a SAR of a wireless terminal should be measured when a mobile terminal approaches a side of a human brain. Thus, how to meet the electromagnetic radiation standards for human bodies while miniaturizing wireless terminals has become an important issue to be solved urgently in the industry.

In a current existing technique, a sensing element is additionally disposed near an antenna element of a wireless terminal, and the sensing element is capacitively coupled to the antenna element and employed to detect whether a human body approaches. When detecting that the human body approaches the antenna element, the sensing element may correspondingly reduce an output power of the antenna element based on a detection result, so as to prevent the human body from being influenced by the electromagnetic wave.

However, because the sensing element is apart from the antenna element by a distance and is capacitively coupled to the antenna element, while it is difficult to control a capacitance and the distance, which may result in not only high interference appearing between the sensing element and the antenna element, but also difficulty in the adjustment of the antenna characteristics. Moreover, the overall antenna length is still long, which causes difficulty in the disposition of the antenna in a miniaturized wireless terminal.

### SUMMARY

Accordingly, the disclosure provides an antenna device, which allows a single antenna element not only to transmit or receive a radiation signal, but also to be employed as a sensing element for sensing whether a human body approaches the antenna device. In this situation, a volume of the antenna device may be reduced, and an issue of interference between the sensing circuit and a control circuit of the antenna element may be eliminated.

The disclosure provides an antenna device including an antenna element, a feeding portion, a filtering circuit and a sensing circuit. The antenna element transmits or receives a radiation signal, wherein the radiation signal includes at least one of a first component and a second component, and a frequency band of the first component is lower than a frequency band of the second component. The feeding portion is coupled to the antenna element. The filtering circuit is coupled to the feeding portion, receives the radiation signal via the feeding portion and filters the second component of the radiation signal to generate a sensing signal. The sensing circuit is coupled to the filtering circuit, receives the sensing signal and determines whether a human body approaches the antenna device based on the sensing signal.

In an embodiment of the disclosure, the filtering circuit includes a high-pass filtering circuit and a low-pass filtering circuit. The high-pass filtering circuit has a first terminal and a second terminal, wherein the first terminal of the high-pass filtering circuit is coupled to the feeding portion, and the second terminal of the high-pass filtering circuit is coupled to a ground terminal. The low-pass filtering circuit has a first terminal and a second terminal, wherein the first terminal of the low-pass filtering circuit is coupled to the first terminal of the high-pass filtering circuit, and the second terminal of the low-pass filtering circuit is coupled to the sensing circuit.

In an embodiment of the disclosure, the high-pass filtering circuit guides the second component of the radiation signal to the ground terminal to remove the second component from the radiation signal.

In an embodiment of the disclosure, the low-pass filtering circuit allows only the first component of the radiation signal to pass through to form the sensing signal.

In an embodiment of the disclosure, the high-pass filtering circuit includes a capacitor.

In an embodiment of the disclosure, the low-pass filtering circuit includes an inductor.

In an embodiment of the disclosure, the first component includes a base frequency component, and the second component includes a radio frequency component.

In an embodiment of the disclosure, when determining that the sensing signal includes only the first component, the sensing circuit determines that the human body approaches the antenna device and outputs a control signal to reduce an output power of the antenna element.

In an embodiment of the disclosure, the feeding portion includes a feeding point, and the feeding point provides the radiation signal including only the second component to be transmitted by the antenna element.

In an embodiment of the disclosure, the antenna element is a planar inverted-F antenna.

To sum up, in the antenna device provided by the embodiments of the disclosure, the second component of the radiation signal can be filtered via the filtering circuit disposed in the antenna device, and only the first component is transmitted to the sensing circuit. Thereby, the antenna element can be employed not only to transmit or receive the radio frequency signal but also to determine whether the human body approaches the antenna device. In this situation, the volume of the antenna device can be effectively reduced, and the issue of interference between the sensing circuit and the control circuit of the antenna element can be eliminated.

To make the above features and advantages of the disclosure more comprehensible, embodiments accompanied with drawings are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram illustrating an antenna device according to an embodiment of the disclosure.

FIG. 2 is a schematic diagram illustrating the antenna device according to the embodiment depicted in FIG. 1.

### DESCRIPTION OF EMBODIMENTS

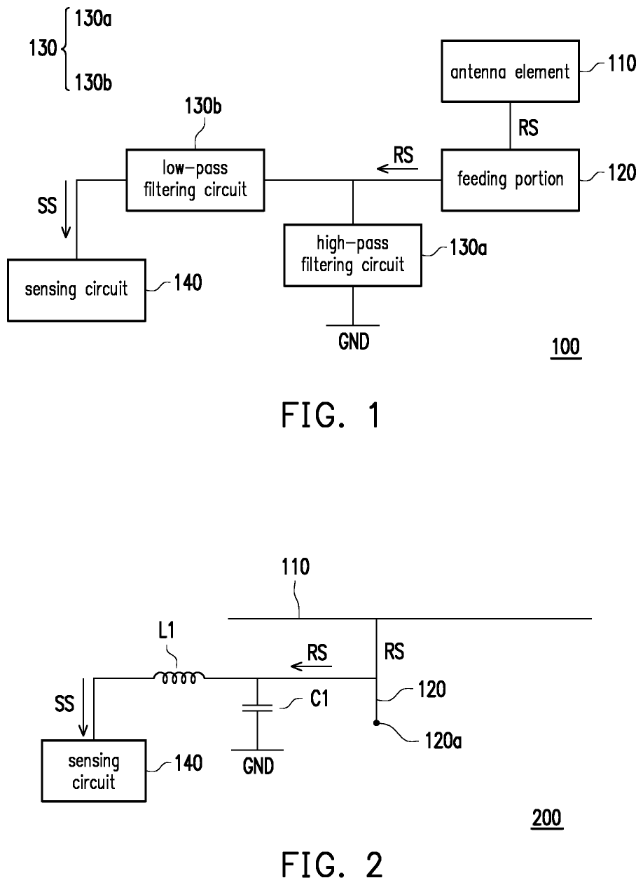

Referring to FIG. 1, FIG. 1 is a schematic diagram illustrating an antenna device according to an embodiment of the disclosure. In the present embodiment, an antenna device 100 includes an antenna element 110, a feeding portion 120, a filtering circuit 130, and a sensing circuit 140. The antenna element 110 transmits or receives a radiation signal RS. The radiation signal RS includes at least one of a first component and a second component, and a frequency band of the first component is lower than a frequency band of the second component. In different embodiments, the antenna element 110 may be a planar inverted-F antenna (PIFA) or any suitable antenna selected by a designer based on the requirements thereof, but the disclosure is limited thereto. In addition, the first component may include a base frequency component of the radiation signal RS, and the second component may include a radio frequency component of the radiation signal RS. The feeding portion 120 is coupled to the antenna element 110 and may excite the antenna element 110 to be operated in one or more frequency bands.

The filtering circuit 130 is coupled to the feeding portion 120. The filtering circuit 130 may receive the radiation signal RS via the feeding portion 120 and filter the second component of the radiation signal RS to generate a sensing signal SS.

In FIG. 1, the filtering circuit 130 may include a high-pass filtering circuit 130a and a low-pass filtering circuit 130b. The high-pass filtering circuit 130a has a first terminal and a second terminal. The first terminal of the high-pass filtering circuit 130a is coupled to the feeding portion 120, and the second terminal of the high-pass filtering circuit 130a is coupled to a ground terminal GND. The low-pass filtering circuit 130b has a first terminal and a second terminal. The first terminal of the low-pass filtering circuit 130b is coupled to the first terminal of the high-pass filtering circuit 130a, and the second terminal of the low-pass filtering circuit 130b is coupled to the sensing circuit 140.

In the present embodiment, the high-pass filtering circuit 130a may guide the second component (e.g., the radio frequency component) in the radiation signal RS to the ground terminal GND to remove the second component from the radiation signal RS. Meanwhile, the low-pass filtering circuit 130b may allow only the first component (e.g., the base frequency component) in the radiation signal RS to pass through to form the sensing signal SS.

The sensing circuit 140 is coupled to the filtering circuit 130, receives the sensing signal SS and determines whether a human body approaches the antenna device 100 based on the sensing signal SS.

In an embodiment of the disclosure, the antenna element 110 is capable of simultaneously transmitting or receiving the radiation signal and sensing whether the human body approaches the antenna device 100. Thus, in a first embodiment, when the antenna element 110 is excited by the feeding portion 120 and employed for transmission, the radiation signal RS provided by the feeding portion 120 may include only the second component (e.g., the radio frequency component), and the antenna element 110 may correspondingly transmit the second component. In an embodiment, when the antenna element 110 is implemented as the PIFA, the second component may include a first sub component and a second sub component belonging to different frequency bands which are radiated respectively via different paths provided by the antenna element 110 (i.e., the PIFA), but the disclosure is not limited thereto.

In this situation, the filtering circuit 130 may receive the radiation signal RS provided by the feeding portion 120, and the second component of the radiation signal RS may be filtered via the high-pass filtering circuit 130a. As described above, because the radiation signal RS provided by the feeding portion 120 may only include the second component (e.g., the radio frequency component)without the first component (e.g., the base frequency component), when the sensing circuit 140 receives the sensing signal SS (which is the radiation signal RS which is filtered by the high-pass filtering circuit 130a and the low-pass filtering circuit 130b), the sensing circuit 140 may determine that no human body approaches the antenna device 100 based on the sensing signal SS. Correspondingly, a power for the antenna element 110 to transmit the radiation signal RS may not have to be adjusted (because the human body would not be affected).

On the other hand, in a second embodiment, when the human body approaches the antenna device 100 and the antenna element 110 does not receive any other signal, the antenna element 110 may sense and correspondingly provide the radiation signal RS including only the first component (e.g., the base frequency component), and the radiation signal RS may be transmitted to the filtering circuit 130 via the feeding portion 120. In this circumstance, the low-pass filtering circuit 130b may allow only the first component (e.g., the base frequency component) of the radiation signal RS to pass through to form the sensing signal SS. In this situation, the sensing circuit 140 may determine that the human body approaches the antenna device 100 based on the sensing signal SS (which includes only the aforementioned first component). Correspondingly, the sensing circuit 140 may transmit a control signal to a related control circuit of the antenna element 110 to reduce an output power of the antenna element 110. Thereby, the antenna element 110, when transmitting other signals in the future, may be prevented from affecting the human body approaching the antenna device 100 due to the output power being overly large.

In a third embodiment, when the human body approaches the antenna device 100 while the antenna element 110 is being employed to receive another signal, the radiation signal RS provided by the antenna element 110 may include both the first component (which is, for example, the base frequency component formed by sensing the human body) and the second component (i.e., the radio frequency component), and the radiation signal RS may be transmitted to the filtering circuit 130 via the feeding portion 120. In this circumstance, the high-pass filtering circuit 130a may guide the second component of the radiation signal RS to the ground terminal GND to remove the second component from the radiation signal RS, and the low-pass filtering circuit 130b may allow only the first component of the radiation signal RS to pass through to form the sensing signal SS. In this situation, the sensing circuit 140 may determine that the human body approaches the antenna device 100 based on the sensing signal SS (which includes only the first component). Correspondingly, the sensing circuit 140 may transmit a control signal to the related control circuit of the antenna element 110 to reduce the output power of the antenna element 110. Thereby, the antenna element 110, when transmitting other signals in the future, may be prevented from affecting the human body approaching the antenna device 100 due to the output power being overly large.

According to the third embodiment described above, when the human body leaves the antenna device 100 while the antenna element 110 is being employed to receive another signal, the radiation signal RS provided by the feeding portion 110 may include only the second component (e.g., the radio frequency component), and the radiation signal RS may be transmitted to the filtering circuit 130 via the feeding portion 120. In this circumstance, the high-pass filtering circuit 130a may guide the second component of the radiation signal RS to the ground terminal GND to remove the second component from the radiation signal RS. In this situation, the sensing circuit 140 may determine that no human body approaches the antenna device 100 based on the sensing signal SS. Correspondingly, the sensing circuit 140 may transmit another control signal to the related control circuit of the antenna element 110, thereby restoring/increasing the output power of the antenna element 110.

In light of the foregoing, in the antenna device provided by the embodiments of the disclosure, the second component of the radiation signal may be filtered via the filtering circuit disposed in the antenna device, and only the first component may be transmitted to the sensing circuit. In this way, the antenna element can be employed not only to transmit or receive the radio frequency signal, but also to determine whether the human body approaches the antenna device. In this situation, the volume of the antenna device may be effectively reduced, and the issue of interference between the sensing circuit and the control circuit of the antenna element can be eliminated.

Referring to FIG. 2, FIG. 2 is a schematic diagram illustrating the antenna device according to the embodiment depicted in FIG. 1. In the present embodiment, an antenna device 200 may be considered as one of the implementation manners of the antenna device 100 illustrated in FIG. 1, wherein the antenna device 110 may be implemented as a PIFA, the high-pass filtering circuit 130a may be implemented as a capacitor C1, the low-pass filtering circuit 130b may be implemented as an inductor L1, and the feeding portion 120 may include a feeding point 120a.

As illustrated in FIG. 2, the capacitor C1 has a first terminal and a second terminal, wherein the first terminal of the capacitor C1 is coupled to the feeding portion 120, and the second terminal of the capacitor C1 is coupled to the ground terminal GND. The inductor L1 has a first terminal and a second terminal, wherein the first terminal of the inductor L1 is coupled to the first terminal of the capacitor C1, and the second terminal of the inductor L1 is coupled to the sensing circuit 140. In an embodiment, an overall impedance matching and frequency bandwidth of the antenna device 100 may be adjusted by adjusting the inductor L1, so as to achieve desired optimal wide-band antenna characteristics.

In the present embodiment, the capacitor C1 may guide the second component (e.g., the radio frequency component) in the radiation signal RS to the ground terminal GND to remove the second component from the radiation signal RS. Meanwhile, the inductor L1 may allow only the first component (e.g., the base frequency component) of the radiation signal RS to pass through to form the sensing signal SS.

Similar to FIG. 1, the antenna element 110 illustrated in FIG. 2 is also capable of simultaneously transmitting or receiving the radiation signal and sensing whether the human body approaches the antenna device 100. Thus, in the first embodiment, when the feeding point 120a provides the radiation signal RS including only the second component (e.g., the radio frequency component) to be transmitted by the antenna element, the antenna element 100 may correspondingly transmit the second component.

In this situation, and the second component of the radiation signal RS may be filtered by the capacitor C1. Based on the above, because the radiation signal RS provided by the feeding point 120a may include only the second component (e.g., the radio frequency component) without the first component (e.g., the base frequency component), when the sensing circuit 140 receives the sensing signal SS (which is the radiation signal RS filtered via the capacitor C1 and the inductor L1), the sensing circuit 140 may determine that no human body approaches the antenna device 100 based on the sensing signal SS. Correspondingly, the power for the antenna element 110 to transmit the radiation signal RS may not be adjusted (because the human body will not be affected).

On the other hand, when the human body approaches the antenna device 100, and the antenna element 110 does not receive any other signal, the antenna element 110 may sense and correspondingly provide the radiation signal RS including only the first component (e.g., the base frequency component), and the radiation signal RS may be transmitted to the filtering circuit 130 via the feeding portion 120. In this circumstance, the inductor L1 may allow only the first component (e.g., the base frequency component) of the radiation signal RS to pass through to form the sensing signal SS. In this situation, the sensing circuit 140 may determine that the human body approaches the antenna device 100 based on the sensing signal SS (which includes only the first component). Correspondingly, the sensing circuit 140 may transmit a control signal to the related control circuit of the antenna element 110 to reduce the output power of the antenna element 110. Thereby, the antenna element 110, when transmitting other signals in the future, may be prevented from affecting the human body approaching the antenna device 100 due to the output power being overly large.

In addition, when the human body approaches the antenna device 100 while the antenna element 110 is being employed to receive another signal, the radiation signal RS provided by the antenna element 110 may include both the first component (which is, for example, the base frequency component formed by sensing the human body) and the second component (i.e., the radio frequency component), and the radiation signal RS may be transmitted to the filtering circuit 130 via the feeding portion 120. In this circumstance, the capacitor C1 may guide the second component of the radiation signal RS to the ground terminal GND to remove the second component from the radiation signal RS, while the inductor L1 may allow only the first component of the radiation signal RS to pass through to form the sensing signal SS. In this situation, the sensing circuit 140 may determine that the human body approaches the antenna device 100 based on the sensing signal SS (which includes only the first component). Correspondingly, the sensing circuit 140 may transmit a control signal to the related control circuit of the antenna element 110 to reduce the output power of the antenna element 110. In this way, the antenna element 110, when transmitting other signals in the future, may be prevented from affecting the human body approaching the antenna device 100 due to the output power being overly large.

Thereafter, when the human body leaves the antenna device 100, while the antenna element 110 is being employed to receive another signal, the radiation signal RS provided by the feeding portion 110 may include only the second component (e.g., the radio frequency component), and the radiation signal RS may be transmitted to the filtering circuit 130 via the feeding portion 120. In this circumstance, the capacitor C1 may guide the second component of the radiation signal RS to the ground terminal GND to remove the second component from the radiation signal RS. In this situation, the sensing circuit 140 may determine that no human body approaches the antenna device 100 based on the sensing signal SS. Correspondingly, the sensing circuit 140 may transmit another control signal to the related control circuit of the antenna element 110, thereby resuming/increasing the output power of the antenna element 110.

It should be understood that the high-pass filtering circuit 130a and the low-pass filtering circuit 130b are respectively implemented by using the capacitor C1 and the inductor L1 in FIG. 2, but it construes no limitations to possible embodiments of the disclosure. In other embodiments, a designer may also implement the high-pass filtering circuit 130a and the low-pass filtering circuit 130b by using required circuits based on a design requirement.

Based on the above, in the antenna device provided by the embodiments of the disclosure, the second component of the radiation signal can be filtered via the filtering circuit disposed in antenna device, and only the first component (e.g., the base frequency component is generated by the antenna element sensing the human body) can be transmitted to the sensing circuit. Thereby, a single antenna element can be employed not only to transmit or receive the radiation signal, but also determine whether the human body approaches the antenna device. In this situation, the volume of the antenna device can be effectively reduced, and the issue of interference between the sensing circuit and the control circuit of the antenna element can be eliminated. Thus, the antenna device of the disclosure can be more adaptively disposed in a miniaturized wireless terminal.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. An antenna device, comprising:
an antenna element, transmitting or receiving a radiation signal, wherein the radiation signal comprises at least one of a first component and a second component, and a frequency band of the first component is lower than a frequency band of the second component;
a feeding portion, coupled to the antenna element;
a filtering circuit, coupled to the feeding portion, receiving the radiation signal via the feeding portion and filtering the second component of the radiation signal to generate a sensing signal; and
a sensing circuit, coupled to the filtering circuit, receiving the sensing signal and determining whether a human body approaches the antenna device based on the sensing signal.

2. The antenna device according to claim 1, wherein the filtering circuit comprises:
a high-pass filtering circuit, having a first terminal and a second terminal, wherein the first terminal of the high-pass filtering circuit is coupled to the feeding portion, and the second terminal of the high-pass filtering circuit is coupled to a ground terminal; and
a low-pass filtering circuit, having a first terminal and a second terminal, wherein the first terminal of the low-pass filtering circuit is coupled to the first terminal of the high-pass filtering circuit, the second terminal of the low-pass filtering circuit is coupled to the sensing circuit.

3. The antenna device according to claim 2, wherein the high-pass filtering circuit guides the second component of the radiation signal to the ground terminal to remove the second component from the radiation signal.

4. The antenna device according to claim 2, wherein the low-pass filtering circuit allows only the first component of the radiation signal to pass through to form the sensing signal.

5. The antenna device according to claim 2, wherein the high-pass filtering circuit comprises a capacitor.

6. The antenna device according to claim 2, wherein the low-pass filtering circuit comprises an inductor.

7. The antenna device according to claim 1, wherein the first component comprises a base frequency component, and the second component comprises a radio frequency component.

8. The antenna device according to claim 1, wherein when determining that the sensing signal comprises only the first component, the sensing circuit determines that the human body approaches the antenna device and outputs a control signal to reduce an output power of the antenna element.

9. The antenna device according to claim 1, wherein the feeding portion comprises a feeding point, and the feeding point provides the radiation signal comprising only the second component to be transmitted by the antenna element.

10. The antenna device according to claim 1, wherein the antenna element is a planar inverted-F antenna.
